(19) United States
(12) Patent Application Publication
(10) Pub. No.: US 2024/0160214 A1
(43) Pub. Date: May 16, 2024

(54) AUTONOMOUS DRIVING DEVICE

(71) Applicant: SEMES CO., LTD., Cheonan-si (KR)

(72) Inventors: Jungwoo KIM, Cheonan-si (KR); Jongwon JUNG, Cheonan-si (KR); Seungju LEE, Cheonan-si (KR)

(73) Assignee: SEMES CO., LTD., Cheonan-si (KR)

(21) Appl. No.: 18/472,877

(22) Filed: Sep. 22, 2023

(30) Foreign Application Priority Data
Nov. 15, 2022 (KR) 10-2022-0152743

(51) Int. Cl. G05D 1/02

(52) U.S. Cl. CPC G05D 1/0274; G05D 1/0214; G05D 1/024; G05D 1/0248; G05D 1/0287; G05D 2201/0216

(57) ABSTRACT

An autonomous driving device includes a plurality of vehicles configured to travel on the ceiling of a manufacturing line in which manufacturing equipment is arranged, a traveling rail arranged along the ceiling of the manufacturing line to provide a movement path for each of the plurality of vehicles, a measurement module mounted on each of the plurality of vehicles and including a LiDAR sensor and a 3-dimensional sensor, and a map generating module configured to receive information from the measurement module, wherein the map generating module is further configured to generate a 3-dimensional map that 3-dimensionally represents the manufacturing line.

### CROSS-REFERENCE TO RELATED APPLICATION

This application is based on and claims priority under 35 U.S.C. § 119 to Korean Patent Application No. 10-2022-0152743, filed on Nov. 15, 2022, in the Korean Intellectual Property Office, the disclosure of which is incorporated by reference herein in its entirety.

### BACKGROUND

### 1. Field

The disclosure relates to an autonomous driving device, and more particularly, to an autonomous driving device capable of monitoring a manufacturing line in real time by forming a 3-dimensional map.

### 2. Description of the Related Art

Hundreds of processes are performed to produce finished semiconductor products, and hundreds of thousands of movements of materials are performed during semiconductor manufacturing processes. To prevent semiconductor materials from suffering from contamination, damage, wrong delivery, and the like during such material transport processes, overhead hoist transport devices are used as material transport automated systems in semiconductor manufacturing lines. Overhead hoist transport devices are systems for automating material transport between numerous semiconductor processes and function to transport wafers contained in front opening unified pods (FOUPs) to manufacturing equipment for each production process along rails mounted on ceilings.

### SUMMARY

Provided is an autonomous driving device capable of controlling driving of a vehicle in real time by forming a 3-dimensional map through the real-time collection of 3-dimensional modeling information while the vehicle travels.

Provided is an autonomous driving device for automatically correcting errors and missing information when an operator fabricates a 2-dimensional map.

Additional aspects will be set forth in part in the description which follows and, in part, will be apparent from the description, or may be learned by practice of the presented embodiments of the disclosure.

According to an aspect of the disclosure, an autonomous driving device includes a plurality of vehicles configured to travel on a ceiling of a manufacturing line in which manufacturing equipment is arranged, a traveling rail arranged along the ceiling of the manufacturing line to provide a movement path for each of the plurality of vehicles, a measurement module mounted on each of the plurality of vehicles and including a LiDAR sensor and a 3-dimensional sensor, and a map generating module configured to receive information from the measurement module, wherein the map generating module is further configured to generate a 3-dimensional map that 3-dimensionally represents the manufacturing line.

According to another aspect of the disclosure, an autonomous driving device includes a plurality of vehicles configured to travel on a floor of a manufacturing line in which manufacturing equipment is arranged, a measurement module mounted on each of the plurality of vehicles and configured to measure a shape and a position of the manufacturing equipment in real time, a map generating module configured to transmit information to and receive information from the measurement module, and a control module configured to control driving of the plurality of vehicles, wherein the map generating module is further configured to generate a 3-dimensional map that 3-dimensionally represents the manufacturing line, and the measurement module is further configured to generate 3-dimensional modeling information including information about a structure of the manufacturing line and a shape and a position of the manufacturing equipment.

According to yet another aspect of the disclosure, an autonomous driving device includes a plurality of vehicles configured to travel on a ceiling of a manufacturing line in which manufacturing equipment is arranged, a traveling rail arranged along the ceiling of the manufacturing line to provide a movement path for each of the plurality of vehicles, a measurement module mounted on each of the plurality of vehicles and including an optical measurement device, a map generating module configured to receive information from the measurement module, and a control module configured to control driving of the plurality of vehicles, wherein the measurement module is configured to generate 3-dimensional modeling information, the 3-dimensional modeling information includes information of the traveling rail, information of the manufacturing equipment, and information of the manufacturing line, the map generating module is further configured to generate a 3-dimensional map that 3-dimensionally represents the manufacturing line, based on a 2-dimensional map representing the manufacturing line as a 2-dimensional grid structure and the 3-dimensional modeling information, and the map generating module is further configured to transmit the 3-dimensional map to the plurality of vehicles and the control module.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a conceptual diagram schematically illustrating an autonomous driving device according to an embodiment;

FIGS. 2 and 3 are configuration diagrams illustrating a vehicle of the autonomous driving device of FIG. 1 in more detail;

FIGS. 4A and 4B are conceptual diagrams illustrating a signal transfer process of an autonomous driving device, according to an embodiment;

FIGS. 5A to 5C are conceptual diagrams illustrating a process in which an autonomous driving device forms a 3-dimensional map, according to an embodiment;

FIG. 6 is a configuration diagram schematically illustrating a vehicle of an autonomous driving device, according to an embodiment;

FIG. 7 is a conceptual diagram schematically illustrating an autonomous driving device according to an embodiment;

FIG. 8 is a perspective view schematically illustrating a vehicle of the autonomous driving device of FIG. 7; and

FIGS. 9A to 9C are conceptual diagrams illustrating a signal transfer process of an autonomous driving device, according to an embodiment.

### DETAILED DESCRIPTION

Reference will now be made in detail to embodiments, examples of which are illustrated in the accompanying drawings, wherein like reference numerals refer to like elements throughout.

In this regard, the present embodiments may have different forms and should not be construed as being limited to the descriptions set forth herein. Accordingly, the embodiments are merely described below, by referring to the figures, to explain aspects of the present description. Although terms used herein are of among general terms which are currently and broadly used by considering functions in the disclosure, these terms may vary according to intentions of those of ordinary skill in the art, precedents, the emergence of new technologies, or the like.

In addition, there may be terms selected arbitrarily by the applicants in particular cases, and in these cases, the meaning of those terms will be described in detail in the corresponding portions of the detailed description. Therefore, the terms used herein should be defined based on the meaning thereof and descriptions made throughout the specification, rather than based on names simply called. The disclosure may have various changes thereto and have various embodiments, and specific embodiments of the disclosure are illustrated in the accompanying drawings and will be described in detail in the following description.

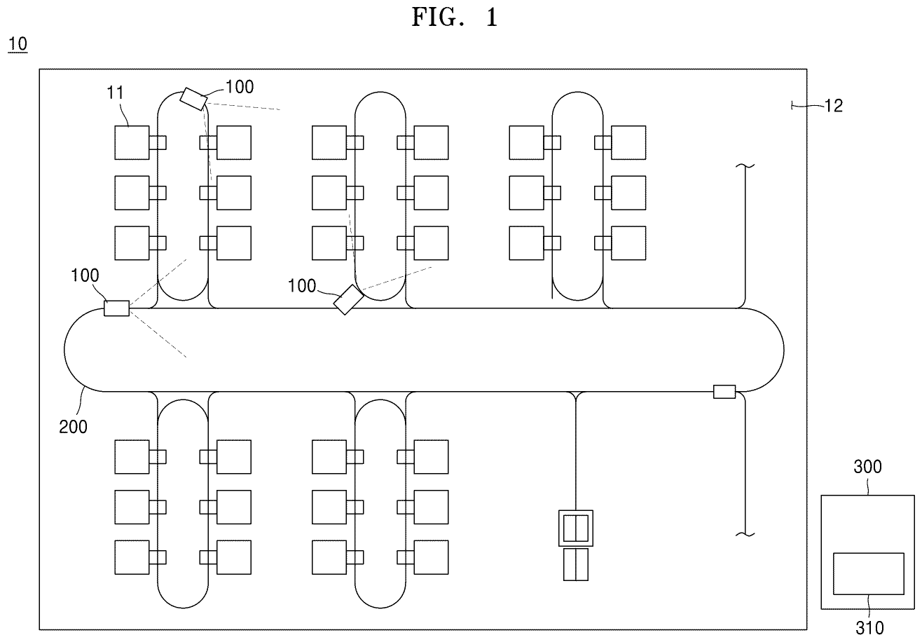

However, it should be appreciated that the disclosure is not limited to these embodiments and all changes, equivalents or replacements thereto belong to the scope of the disclosure. The terms used herein are only for describing embodiments of the disclosure and are not intended to limit the disclosure. FIG. 1 is a conceptual diagram schematically illustrating an autonomous driving device according to an embodiment.

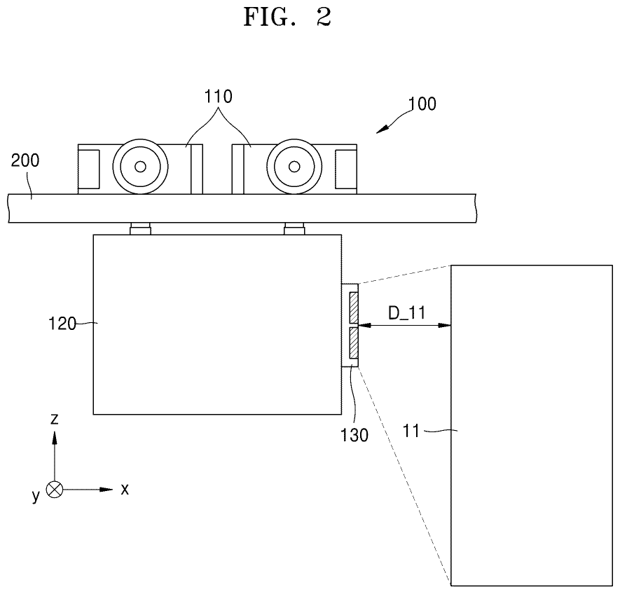

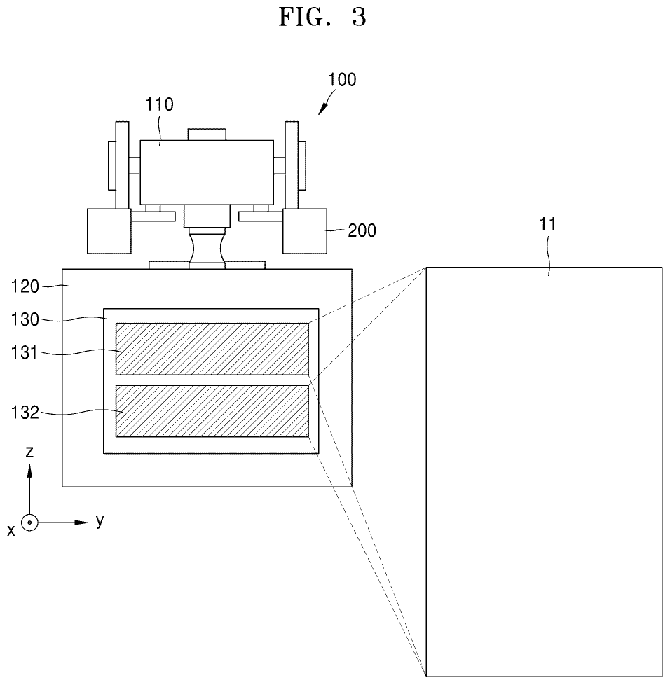

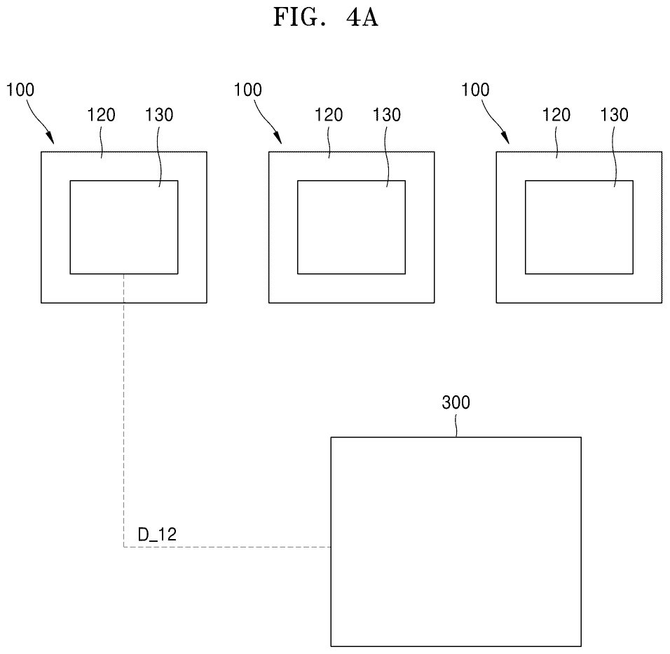

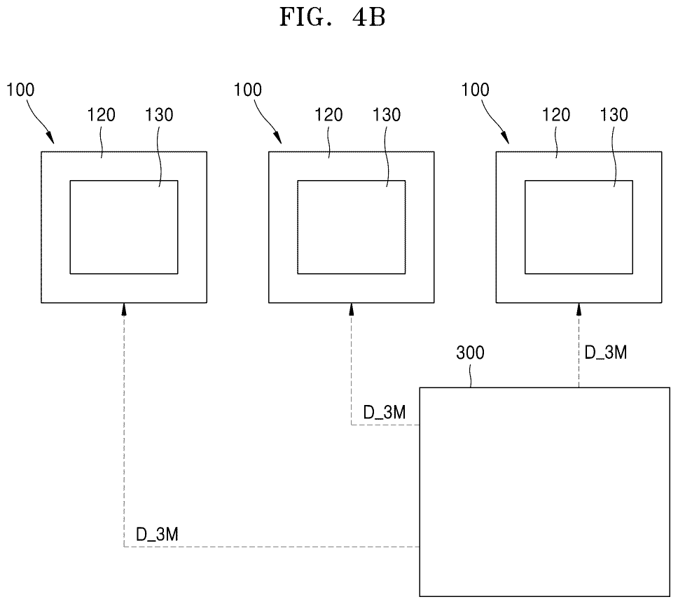

FIGS. 2 and 3 are configuration diagrams illustrating a vehicle of the autonomous driving device of FIG. 1 in more detail. FIGS. 4A and 4B are conceptual diagrams illustrating a signal transfer process of an autonomous driving device, according to an embodiment. Referring to FIGS. 1 to 4B, an autonomous driving device 10 may include a plurality of vehicles 100, a traveling rail 200, a measurement module 130, and a map generating module 300.

Hereinafter, an extension direction of the traveling rail 200 is defined as an X direction, a direction that is perpendicular to the X direction is defined as a Y direction, and a direction that is perpendicular to each of the X direction and the Y direction is defined as a Z direction.

That is, a Z axis may be an axis that is perpendicular to the ceiling of a manufacturing line 12. The plurality of vehicles 100 of the autonomous driving device 10 may travel on the ceiling of the manufacturing line 12.

Manufacturing equipment 11 may be arranged in the manufacturing line 12. That is, the plurality of vehicles 100 may travel on the ceiling of the manufacturing line 12, in which the manufacturing equipment 11 is arranged. In some embodiments, the plurality of vehicles 100 may each include a conveying-object transport vehicle.

That is, each of the plurality of vehicles 100 may have a space which the conveying-object is loaded in and unloaded from. Each of the plurality of vehicles 100 may be configured to transport the conveying-object. The conveying-object includes wafers, glass substrates, printed circuit boards, semiconductor devices, display devices, and the like, which are used in a manufacturing process of a semiconductor device or a display device. In some embodiments, a vehicle 100 may include a driving module 110 and an elevation module 120.

The driving module 110 may cause the vehicle 100 to move on the traveling rail 200. The elevation module 120 may be configured to be connected to a lower portion of the driving module 110 in a suspended manner, via a rotation shaft. According to embodiments, the elevation module 120 may be configured to allow containers containing substrates to move up and down. The traveling rail 200 of the autonomous driving device 10 may provide a movement path for each of the plurality of vehicles 100.

The traveling rail 200 may be arranged along the ceiling of the manufacturing line 12. That is, the traveling rail 200 may provide a path for the plurality of vehicles 100 to move along the ceiling of the manufacturing line 12. In other words, the plurality of vehicles 100 may travel on the ceiling of the manufacturing line 12 along the traveling rail 200. In addition, the traveling rail 200 may be arranged along the ceiling of the manufacturing line 12 and may have a shape varying with an arrangement of the manufacturing equipment 11. The measurement module 130 of the autonomous driving device 10 may be mounted on the vehicle 100.

In some embodiments, the measurement module 130 may be mounted outside the elevation module 120 of the vehicle 100. In some embodiments, the measurement module 130 may include a LiDAR sensor 131 and a 3-dimensional sensor 132.

The LiDAR sensor 131 may sense a distance D_11 between the manufacturing equipment 11 and the LiDAR sensor 131 and various material properties by laser irradiation in forward and lateral directions of the vehicle 100. The 3-dimensional sensor 132 may 3-dimensionally measure the manufacturing line 12 and the manufacturing equipment 11 and may analyze information thereof. That is, the measurement module 130 may collect the information of the manufacturing line 12 and the manufacturing equipment 11 via the LiDAR sensor 131 and the 3-dimensional sensor 132. Although FIGS. 2 and 3 illustrate an example in which the measurement module 130 includes the LiDAR sensor 131 and the 3-dimensional sensor 132, the disclosure is not limited thereto, and the measurement module 130 may further include a temperature sensor, a humidity sensor, or an acceleration sensor. In some embodiments, the measurement module 130 may measure a structure of the manufacturing line 12 and a position of the manufacturing equipment 11 when the vehicle 100 is traveling.

In other words, the measurement module 130 attached to the vehicle 100 may move together with the vehicle 100 when the vehicle 100 is traveling. The measurement module 130 moving together with the vehicle 100 may measure the structure of the manufacturing line 12 and the position of the manufacturing equipment 11 when the vehicle 100 is traveling. In FIGS. 1 to 3, it is illustrated by dashed lines that the measurement module 130 is attached to the vehicle 100 and measures the manufacturing line 12 and the manufacturing equipment 11. In some embodiments, the measurement module 130 may generate 3-dimensional modeling information D_12.

The measurement module 130 may transmit the 3-dimensional modeling information D_12 to the map generating module 300. The 3-dimensional modeling information D_12 may include the structure of the manufacturing line 12, the shape of the manufacturing equipment 11, and the position of the manufacturing equipment 11. More specifically, the 3-dimensional modeling information D_12 may include: information about the traveling rail 200, such as curves and slopes of the traveling rail 200 and the presence or not of obstacles on the traveling rail 200; information about the manufacturing line 12, such as respective slopes of the ceiling and the floor of the manufacturing line 12 and the presence or not of obstacles in the manufacturing line 12; and information about the manufacturing equipment 11, such as the position of the manufacturing equipment 11 and the presence or not of damage to the manufacturing equipment 11. In some embodiments, the 3-dimensional modeling information D_12 may include tag information indicating a position of the traveling rail 200. The map generating module 300 of the autonomous driving device 10 may receive information from the measurement module 130.

In some embodiments, the map generating module 300 may receive the 3-dimensional modeling information D_12 from the measurement module 130. The map generating module 300 may be arranged apart from the plurality of vehicles 100. In some embodiments, the map generating module 300 may wirelessly receive information from the measurement module 130. The map generating module 300 may generate a 3-dimensional map D_3M.

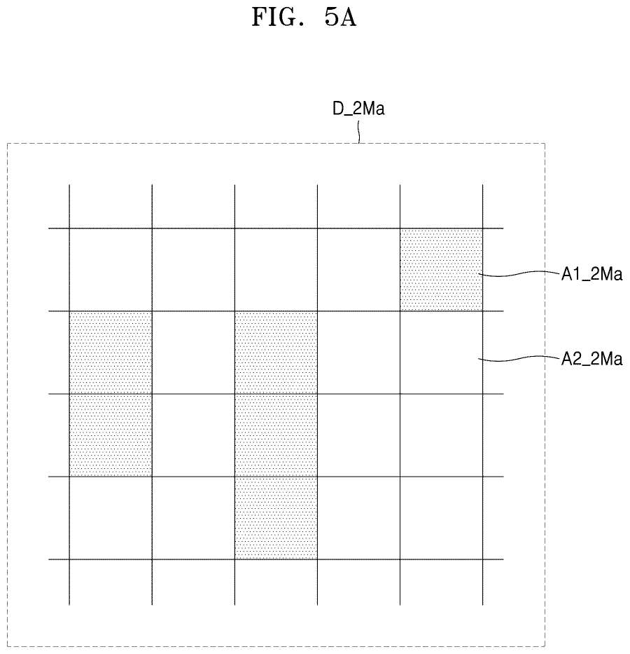

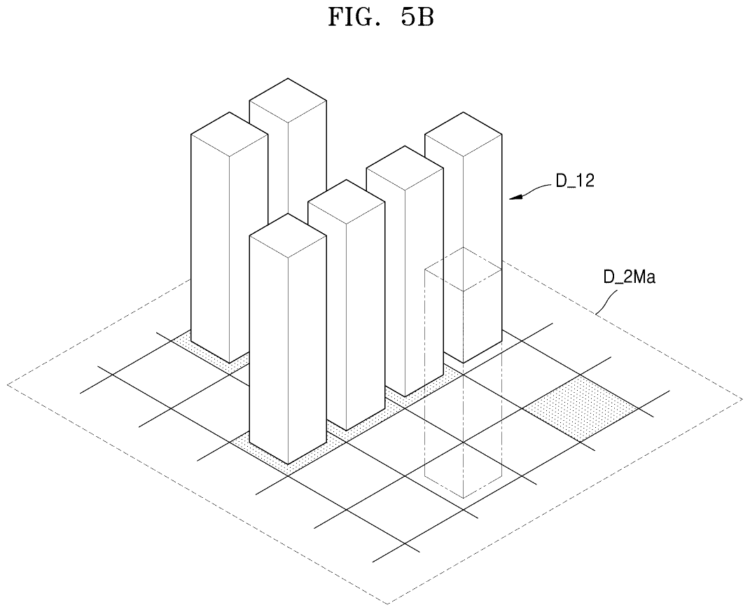

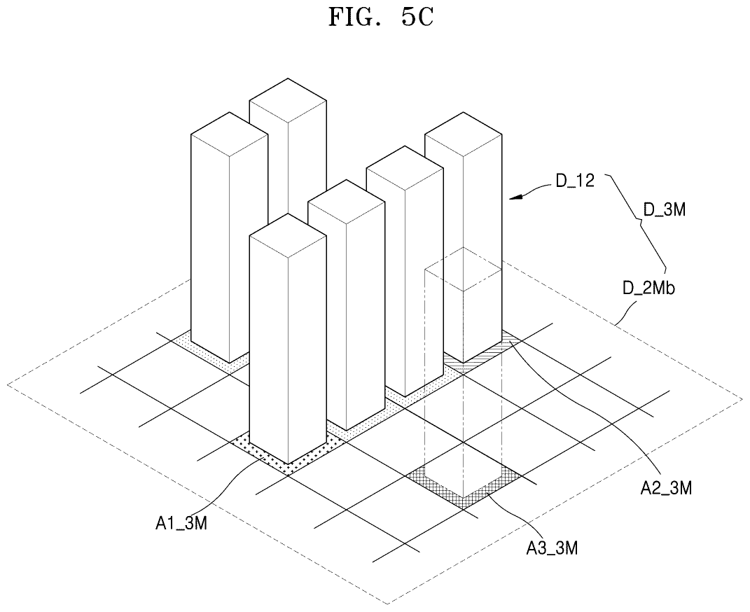

The 3-dimensional map D_3M is a map that 3-dimensionally represents the manufacturing line 12. Specifically, the 3-dimensional map D_3M may be a map formed by merging a 2-dimensional map (for example, D_2Mb of FIG. 5C) with the 3-dimensional modeling information D_12. A process of forming the 3-dimensional map D_3M is described below with reference to FIGS. 5A to 5C. The map generating module 300 may transmit the 3-dimensional map D_3M to the plurality of vehicles 100.

That is, the map generating module 300 may form the 3-dimensional map D_3M and collectively transmit the 3-dimensional map D_3M to the plurality of vehicles 100. In some embodiments, before forming the 3-dimensional map D_3M and transmitting the 3-dimensional map D_3M to the plurality of vehicles 100, the map generating module 300 may transmit the 3-dimensional map D_3M to one vehicle 100, thereby comparing the 3-dimensional map D_3M with the manufacturing line 12. That is, the map generating module 300 may generate the 3-dimensional map D_3M, based on the 3-dimensional modeling information D_12, which is received from the measurement module 130, and a 2-dimensional map (for example, D_2Ma of FIG. 5A).

The generated 3-dimensional map D_3M may be transmitted to the plurality of vehicles 100, thereby controlling driving of the plurality of vehicles 100. Each of the plurality of vehicles 100 receiving the 3-dimensional map D_3M may control the driving module 110. Because the autonomous driving device 10 of the disclosure may collect the 3-dimensional modeling information D_12 via the measurement module 130, the autonomous driving device 10 may find out errors and missing information in advance by comparing the 3-dimensional modeling information D_12 with an existing stored map of the manufacturing line 12.

In addition, because the position of the manufacturing equipment 11 may be accurately identified, offset information for the position of the manufacturing equipment 11 may be added to the 3-dimensional map D_3M to modify the 3-dimensional map D_3M. In some embodiments, the autonomous driving device 10 may check a sheathing condition and a grounding condition of a cable mounted on the traveling rail 200 by measuring the information of the traveling rail 200 via the measurement module 130, and the autonomous driving device 10 may check information about obstacles, such as thin wires, located on the traveling rail 200 and thus reflect the information about obstacles into the 3-dimensional map D_3M in real time.

In some embodiments, because the autonomous driving device 10 may measure and store the tag information of the traveling rail 200 via the measurement module 130, when the structure of the manufacturing line 12 and the position of the manufacturing equipment 11 are changed, the autonomous driving device 10 may automatically store changed tag information and missing tag information.

In addition, instead of using an existing method of dividing and then measuring the manufacturing line 12 during the process of forming the 3-dimensional map D_3M, the tag information of the traveling rail 200 may be measured in real time by the plurality of vehicles 100 that are traveling, thereby reducing errors due to missing tag information of the manufacturing line 12. FIGS. 5A to 5C are conceptual diagrams illustrating a process in which an autonomous driving device forms a 3-dimensional map, according to an embodiment.

A process in which the map generating module 300 generates the 3-dimensional map D_3M is described in more detail with reference to FIGS. 1 to 5C.

FIG. 5A is a diagram schematically illustrating an existing 2-dimensional map D_2Ma.

The map generating module 300 may generate the 3-dimensional map D_3M, based on the existing 2-dimensional map D_2Ma and the 3-dimensional modeling information D_12. The existing 2-dimensional map D_2Ma may be a map representing the manufacturing line 12 as a 2-dimensional grid structure. In some embodiments, the floor of the manufacturing line 12 may be divided by a 2-dimensional grid structure and divided into manufacturing equipment-located regions A1_2Ma and manufacturing equipment-free regions A2_2Ma. In some embodiments, the manufacturing equipment-located regions A1_2Ma may be marked separately and thus be distinguished from the manufacturing equipment-free regions A2_2Ma. FIG. 5B is a diagram schematically illustrating an example of generating the 3-dimensional map D_3M by using the existing 2-dimensional map D_2Ma and the 3-dimensional modeling information D_12.

The map generating module 300 may generate the 3-dimensional map D_3M based on the existing 2-dimensional map D_2Ma and the 3-dimensional modeling information D_12. In some embodiments, the 3-dimensional map D_3M may be a map that 3-dimensionally represents the manufacturing line 12 and the manufacturing equipment 11 by adding information about the manufacturing line 12 and the manufacturing equipment 11 to the existing 2-dimensional map D_2Ma. That is, the 3-dimensional map D_3M may be generated by adding information about the traveling rail 200, the manufacturing line 12, and the manufacturing equipment 11 to the existing 2-dimensional map D_2Ma that 2-dimensionally represents the manufacturing line 12. In some embodiments, the 3-dimensional map D_3M may include shape and position information of the manufacturing equipment 11, the tag information of the traveling rail 200, and slope or obstacle information of the manufacturing line 12. FIG. 5C is a diagram schematically illustrating an example of generating the 3-dimensional map D_3M including a new 2-dimensional map D_2Mb, in which missing information from the existing 2-dimensional map D_2Ma is restored by comparing the 3-dimensional modeling information D_12 with the existing 2-dimensional map D_2Ma.

In some embodiments, the map generating module 300 may train the existing 2-dimensional map D_2Ma, based on the 3-dimensional map D_3M.

That is, the information of the manufacturing line 12 and the manufacturing equipment 11 shown in the 3-dimensional map D_3M may be compared with the information thereof shown in the existing 2-dimensional map D_2Ma, and thus, the new 2-dimensional map D_2Mb may be generated by adding information of the 3-dimensional map D_3M to the existing 2-dimensional map D_2Ma. In other words, the map generating module 300 may generate the new 2-dimensional map D_2Mb that is changed, by training the existing 2-dimensional map D_2Ma regarding missing or changed information from the existing 2-dimensional map D_2Ma about the manufacturing line 12 and the manufacturing equipment 11. The 3-dimensional map D_3M may include the new 2-dimensional map D_2Mb and the 3-dimensional modeling information D_12. In some embodiments, the map generating module 300 may generate the 3-dimensional map D_3M including a map in which the 3-dimensional modeling information D_12 missing from the existing 2-dimensional map D_2Ma is restored by comparing the 3-dimensional modeling information D_12 with the existing 2-dimensional map D_2Ma.

That is, when the manufacturing line 12 is changed after the existing 2-dimensional map D_2Ma is stored, there may be differences between the 3-dimensional modeling information D_12 measured by the measurement module 130 and the existing 2-dimensional map D_2Ma. As the 3-dimensional modeling information D_12 is added to the existing 2-dimensional map D_2Ma, the 3-dimensional map D_3M may include the new 2-dimensional map D_2Mb including changed information about the existing 2-dimensional map D_2Ma by modifying the existing 2-dimensional map D_2Ma. In some embodiments, the 3-dimensional map D_3M generated by the map generating module 300 may divide the manufacturing line 12 into a plurality of regions.

That is, the map generating module 300 may add the 3-dimensional modeling information D_12 to the new 2-dimensional map D_2Mb in which the manufacturing line 12 is divided by a grid structure, and may divide the 3-dimensional map D_3M into a plurality of regions according to the 3-dimensional modeling information D_12. In some embodiments, the 3-dimensional map D_3M may be divided into a first region A1_3M and a second A2_3M.

The first region A1_3M may be a region in which manufacturing equipment abnormally operating is located. The second region A2_3M may be a region in which there is a difference between the existing 2-dimensional map D_2Ma and the 3-dimensional modeling information D_12. In other words, the first region A1_3M may be a region in which manufacturing equipment out of order is located, and the second region A2_3M may be a region in which there is missing information from the existing 2-dimensional map D_2Ma, that is, there is an error in the existing 2-dimensional map D_2Ma. In some embodiments, the 3-dimensional map D_3M may be divided into the first region A1_3M, the second A2_3M, and a third region A3_3M.

The first region A1_3M may be a region in which abnormal manufacturing equipment is located, the second A2_3M may be a region in which there is missing information from the existing 2-dimensional map D_2Ma, and the third region A3_3M may be a region in which the manufacturing equipment 11 is due to be installed. That is, the 3-dimensional map D_3M may include the 3-dimensional modeling information D_12 obtained by measuring the position and shape of the manufacturing equipment 11 of the manufacturing line 12 in real time, and may show what has changed in real time. In some embodiments, the autonomous driving device 10 may further include a display 310.

The display 310 may display the 3-dimensional map D_3M. In some embodiments, the display 310 may be mounted on or mounted separately from the map generating module 300. Alternatively, the display 310 may be provided in a wearable form that may be easily viewed by an operator. FIG. 5C illustrates the 3-dimensional map D_3M displayed on the display 310.

That is, an operator may check the 3-dimensional map D_3M via the display 310. In addition, the operator may identify a plurality of regions, which are divided, of the 3-dimensional map D_3M and may determine whether there is an error in each region. In some embodiments, the 3-dimensional map D_3M may be divided into a plurality of regions, and the plurality of regions may be displayed on the display 310.

In other words, the plurality of regions may be respectively displayed in different colors on the display 310. That is, for the operator to identify information about the manufacturing line 12 and the manufacturing equipment 11 through the 3-dimensional map D_3M displayed on the display 310, the plurality of regions of the 3-dimensional map D_3M may be respectively displayed in different colors. In some embodiments, the 3-dimensional map D_3M may include the first region A1_3M and the second region A2_3M, and the display 310 may respectively represent the first region A1_3M and the second region A2_3M in different colors.

That is, the display 310 may represent the first region A1_3M in a first color and represent the second region A2_3M in a second color that is different from the first color. In some embodiments, the first region A1_3M may be a region in which manufacturing equipment abnormally operating is located. The second region A2_3M may be a region in which there is a difference between the existing 2-dimensional map D_2Ma and the 3-dimensional modeling information D_12. The operator may easily identify the manufacturing equipment 11, which is out of order, and wrong portions of the existing 2-dimensional map D_2Ma, through the 3-dimensional map D_3M displayed in the first color and the second color. In some embodiments, the 3-dimensional map D_3M may include the first region A1_3M, the second region A2_3M, and the third region A3_3M, and the display 310 may respectively represent the first region A1_3M, the second region A2_3M, and the third region A3_3M in different colors.

The first region A1_3M may be a region in which manufacturing equipment abnormally operating is located. The second region A2_3M may be a region in which there is a difference between the existing 2-dimensional map D_2Ma and the 3-dimensional modeling information D_12. The third region A3_3M may be a region in which manufacturing equipment is due to be installed. In some embodiments, the display 310 may display the first region A1_3M in yellow, the second region A2_3M in red, and the third region A3_3M in green. The autonomous driving device 10 of the disclosure may collect the 3-dimensional modeling information D_12 via the measurement module 130, and thus, may find out errors and missing information in advance by comparing the 3-dimensional modeling information D_12 with an existing stored map of the manufacturing line 12.

In addition, the autonomous driving device 10 may accurately identify the position of the manufacturing equipment 11, thereby adding offset information for the position of the manufacturing equipment 11 to the 3-dimensional map D_3M to modify the 3-dimensional map D_3M. In some embodiments, the autonomous driving device 10 may check a sheathing condition and a grounding condition of a cable mounted on the traveling rail 200 by measuring the information of the traveling rail 200 via the measurement module 130, and the autonomous driving device 10 may check information about obstacles, such as thin wires, located on the traveling rail 200 and thus reflect the information about obstacles into the 3-dimensional map D_3M in real time.

In some embodiments, because the autonomous driving device 10 may measure and store the tag information of the traveling rail 200 via the measurement module 130, when the structure of the manufacturing line 12 and the position of the manufacturing equipment 11 are changed, the autonomous driving device 10 may automatically store changed tag information and missing tag information.

In addition, instead of using an existing method of dividing and then measuring the manufacturing line 12 during the process of forming the 3-dimensional map D_3M, the tag information of the traveling rail 200 may be measured in real time by the plurality of vehicles 100 that are traveling, thereby reducing errors due to missing tag information of the manufacturing line 12. In some embodiments, the autonomous driving device 10 may generate the 3-dimensional map D_3M via the map generating module 300 and may transmit the 3-dimensional map D_3M to the plurality of vehicles 100.

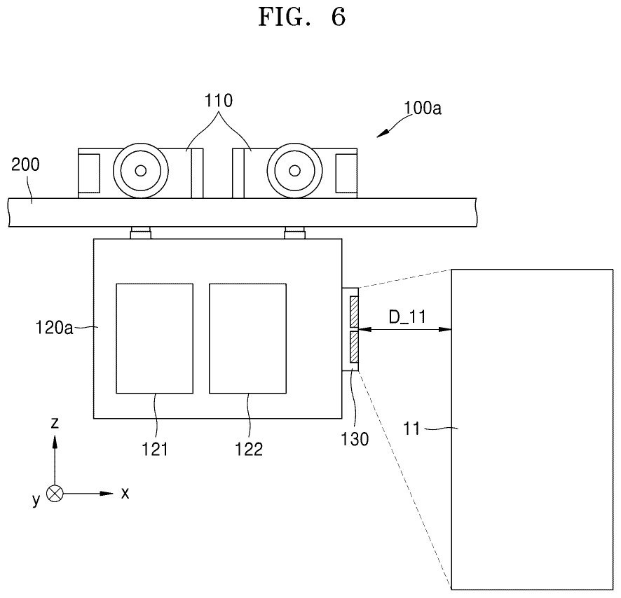

The plurality of vehicles 100 may respectively change driving conditions, based on the 3-dimensional map D_3M changing in real time. That is, each of the plurality of vehicles 100 may control the driving condition thereof according to conditions of the manufacturing line 12 and the manufacturing equipment 11, which change in real time. FIG. 6 is a configuration diagram schematically illustrating a vehicle of an autonomous driving device, according to an embodiment.

Hereinafter, what is common between a vehicle 100a of an autonomous driving device of FIG. 6 and the vehicle 100 of the autonomous driving device 10 of FIG. 2 is omitted, and differences therebetween are described.

Referring to FIG. 6, the measurement module 130 may further include a vibration sensor 121 and a noise sensor 122.

When the vehicle 100a is traveling, the vibration sensor 121 and the noise sensor 122 of the measurement module 130 may respectively measure vibration and noise generated around the vehicle 100a. That is, the measurement module 130 may measure vibration and noise generated by the manufacturing equipment 11, via the vibration sensor 121 and the noise sensor 122, respectively. In other words, the vibration sensor 121 and the noise sensor 122 of the measurement module 130 may be attached to the vehicle 100a and may measure the vibration and noise of the manufacturing equipment 11 installed around the vehicle 100a. In some embodiments, the vibration sensor 121 and the noise sensor 122 may be attached to an elevation module 120a of the vehicle 100a. The measurement module 130 of the autonomous driving device 10 of the disclosure may measure vibration and noise generated in the manufacturing line 12.

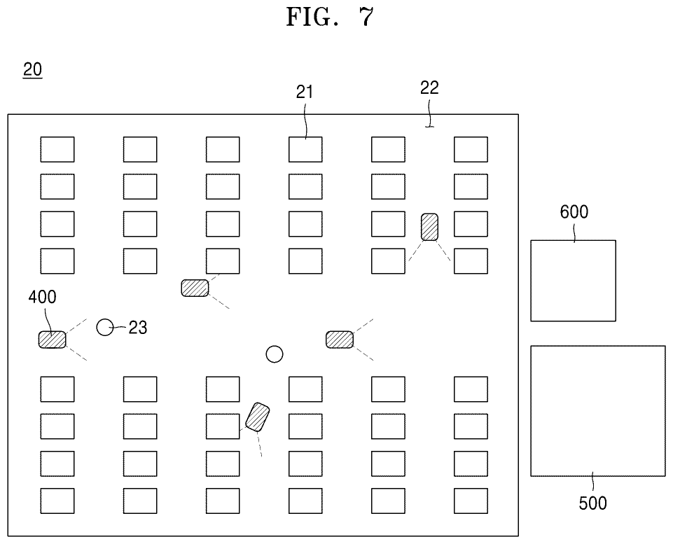

Specifically, the measurement module 130 may measure the vibration and noise generated by the manufacturing equipment 11 around the vehicle 100a. Whether the manufacturing equipment 11 is out of order may be determined by measuring the vibration and noise of the manufacturing equipment 11. In addition, the position of the manufacturing equipment 11 out of order may be shown via the 3-dimensional map D_3M, and an operator may recognize the failure of the manufacturing equipment 11 via the display 310. FIG. 7 is a conceptual diagram schematically illustrating an autonomous driving device 20 according to an embodiment.

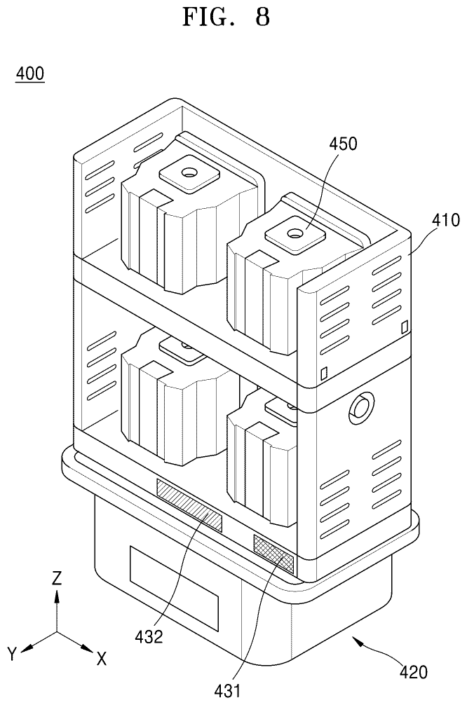

FIG. 8 is a perspective view schematically illustrating a vehicle 400 of the autonomous driving device 20 of FIG. 7. Referring to FIGS. 7 and 8, the autonomous driving device 20 may include a plurality of vehicles 400, a measurement module 431, a map generating module 500, and a control module 600.

Hereinafter, what is common between the autonomous driving device 20 of FIG. 7 and the autonomous driving device 10 of FIG. 1 is omitted, and differences therebetween are described. The plurality of vehicles 400 of the autonomous driving device 20 may travel on the floor of the manufacturing line 12.

That is, the plurality of vehicles 400 may travel on the ground in the manufacturing line 12. In some embodiments, each of the plurality of vehicles 400 may include a housing 410 and a drive unit 420.

A conveying-object may be loaded in and unloaded from the housing 410. A carrier 450, which the conveying-object is loaded in and unloaded from, may be loaded in the housing 410. In other words, the housing 410 may include a loading space. The conveying-object or the carrier 450 may be loaded in the loading space. The housing 410 may have a multi-storied structure. The drive unit 420 of each of the plurality of vehicles 400 may be configured to move the housing 410.

The drive unit 420 may be mounted under the housing 410 and may move the housing 410 to a destination. In other words, the housing 410 may be driven by the drive unit 420. The drive unit 420 may include a battery, a motor, and wheels. A charging method of the battery of the drive unit 420 may include a wired charging method or a wireless charging method. The measurement module 431 of the autonomous driving device 20 may be mounted on each of the plurality of vehicles 400.

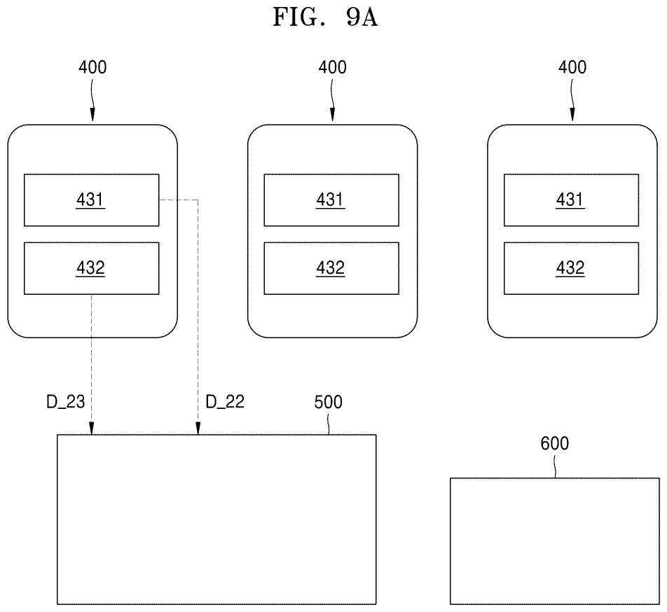

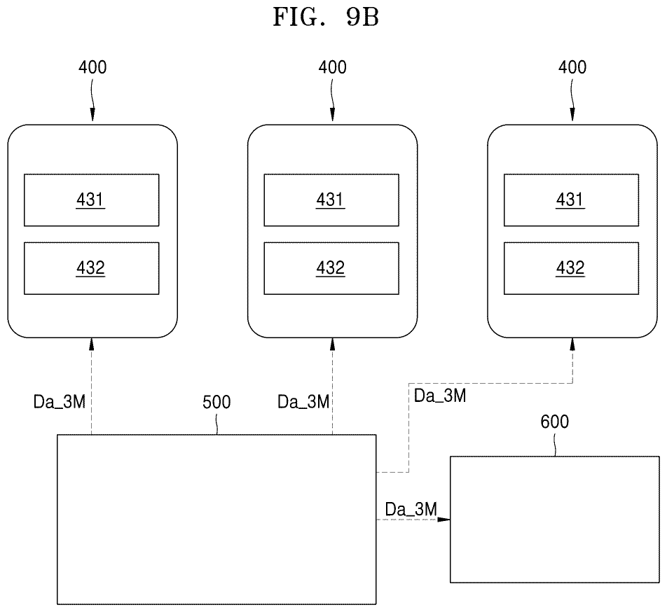

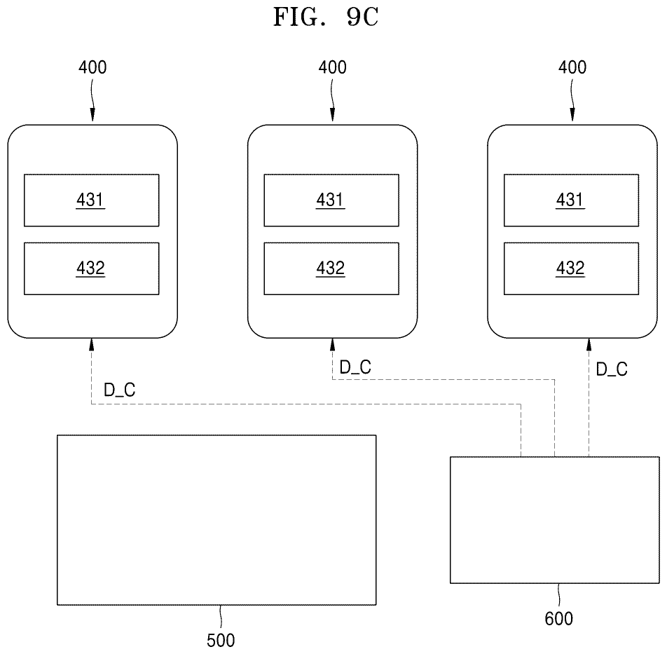

That is, the plurality of vehicles 400 may correspond one-to-one to measurement modules 431. The measurement module 431 may measure a shape of manufacturing equipment 21 and a position of the manufacturing equipment 21. The measurement module 431 may generate 3-dimensional modeling information (for example, D_22 of FIG. 9A) including information about a structure of a manufacturing line 22 and the shape and position of the manufacturing equipment 21. That is, the measurement module 431 may generate the 3-dimensional modeling information by measuring the shape and position of the manufacturing equipment 21. The measurement module 431 may transfer the 3-dimensional modeling information to the map generating module 500. In some embodiments, the 3-dimensional modeling information (for example, D_22 of FIG. 9A) may include the structure of the manufacturing line 22, the shape of the manufacturing equipment 21, and the position of the manufacturing equipment 21.

More specifically, the 3-dimensional modeling information may include information about the manufacturing line 22, such as the slope of the ceiling of the manufacturing line 22, the slope of the floor of the manufacturing line 22, and the presence or not of obstacles in the manufacturing line 22, and information about the manufacturing equipment 21, such as the position of the manufacturing equipment 21 and the presence or not of damage to the manufacturing equipment 21. In some embodiments, the measurement module 431 may include a LiDAR sensor, a 3-dimensional sensor, or an infrared sensor.

In other words, the measurement module 431 may include an optical measurement device. That is, the measurement module 431 may include a measurement device capable of measuring a shape of an object therearound or a separation distance from the object therearound by using optics. In some embodiments, the autonomous driving device 20 may further include an obstacle sensing module 432.

The obstacle sensing module 432 may be attached to the vehicle 400 and thus may move together with the vehicle 400 when the vehicle 400 is traveling. The obstacle sensing module 432 may sense an obstacle 23 located in the manufacturing line 22 while moving together with the vehicle 400. In other words, the obstacle sensing module 432 may sense the obstacle 23 located on a path of the vehicle 400, in real time. The obstacle sensing module 432 may transmit obstacle information (for example, D_23 of FIG. 9A) to the map generating module 500. The map generating module 500 of the autonomous driving device 20 may transmit information to and receive information from the measurement module 431.

In some embodiments, the map generating module 500 may receive the 3-dimensional modeling information generated by the measurement module 431. The map generating module 500 may generate a 3-dimensional map (for example, Da_3M of FIG. 9B).

The 3-dimensional map is a map that 3-dimensionally represents the manufacturing line 22. Specifically, the 3-dimensional map may be a map formed by merging the 2-dimensional map D_2Mb (see FIG. 5A) with the 3-dimensional modeling information (for example, D_22 of FIG. 9A). In some embodiments, the 3-dimensional map may be a map formed by merging the 2-dimensional map D_2Mb (see FIG. 5A), the 3-dimensional modeling information, and the obstacle information (for example, D_23 of FIG. 9A). In some embodiments, a process of generating the 3-dimensional map (for example, Da_3M of FIG. 9B) may include the process of generating the 3-dimensional map D_3M (see FIG. 5C), which is described with reference to FIGS. 5A to 5C. In some embodiments, the map generating module 500 may store the position of the manufacturing equipment 21, which is measured by the measurement module 431, in the 3-dimensional map (for example, Da_3M of FIG. 9B).

In other words, the measurement module 431 may generate the 3-dimensional modeling information (for example, D_22 of FIG. 9A) including position information of the manufacturing equipment 21. The measurement module 431 may transmit the 3-dimensional modeling information to the map generating module 500, and thus, the map generating module 500 may generate the 3-dimensional map including the 3-dimensional modeling information. Due to the 3-dimensional map including the position of the manufacturing equipment 21, the autonomous driving device 20 may find an offset value of the manufacturing equipment 21 located in the manufacturing line 22 and may store the offset value without missing. In some embodiments, the obstacle information (for example, D_23 of FIG. 9A) may be stored in the 3-dimensional map (for example, Da_3M of FIG. 9B).

The obstacle sensing module 432 may generate the obstacle information of the manufacturing line 22, and the map generating module 500 may generate the 3-dimensional map based on the obstacle information. The 3-dimensional map may reflect the obstacle information of the manufacturing line 22 in real time. The 3-dimensional map generated as such may reduce the workload of an operator and may allow the presence or not of an obstacle to be identified for each region of the manufacturing line 22. The control module 600 of the autonomous driving device 20 may control driving of the plurality of vehicles 400.

The control module 600 may receive the 3-dimensional map from the map generating module 500. In addition, the control module 600 may transmit a control signal (for example, D_C of FIG. 9C) to each of the plurality of vehicles 400, based on the 3-dimensional map. In other words, the control module 600 may transmit the control signal for adjusting the traveling path and speed of each of the plurality of vehicles 400, based on the 3-dimensional map. That is, the traveling path and speed of each of the plurality of vehicles 400 may be adjusted by the control signal generated based on the 3-dimensional map that is generated in real time. In some embodiments, when the obstacle 23 located in the manufacturing line 22 is sensed by the obstacle sensing module 432, the obstacle sensing module 432 may transfer the obstacle information (for example, D_23 of FIG. 9A) to the map generating module 500, and the map generating module 500 may generate the 3-dimensional map to which the obstacle information is added.

The 3-dimensional map generated as such may be transferred to the control module 600, and the control module 600 may collectively transfer the control signal to the plurality of vehicles 400, respectively. 3-dimensional map generation and signal transfer processes are described below in detail with reference to FIGS. 9A to 9C. FIGS. 9A to 9C are conceptual diagrams illustrating a signal transfer process of an autonomous driving device, according to an embodiment.

A process of generating the control signal D_C based on information measured by the measurement module 431 or the obstacle sensing module 432 of the autonomous driving device 20 is described with reference to FIGS. 7 to 9C.

FIG. 9A illustrates that the measurement module 431 of at least one of the plurality of vehicles 400 transmits the 3-dimensional modeling information D_22 to the map generating module 500, and that the obstacle sensing module 432 transmits the obstacle information D_23 to the map generating module 500.

In some embodiments, the measurement module 431 attached to each of the plurality of vehicles 400 may transmit, in real time, information of the manufacturing line 22 and information of the manufacturing equipment 21 around the vehicle 400 to the map generating module 500.

When sensing the obstacle 23, the obstacle sensing module 432 attached to each of the plurality of vehicles 400 may transmit the obstacle information D_23 to the map generating module 500. Alternatively, the obstacle sensing module 432 may transmit the presence or not of the obstacle 23 to the map generating module 500 in real time. FIG. 9B illustrates that the map generating module 500 generates the 3-dimensional map Da_3M based on the 3-dimensional modeling information D_22 and the obstacle information D_23 and then transmits the 3-dimensional map Da_3M to the plurality of vehicles 400 and the control module 600.

In some embodiments, the map generating module 500 may generate the 3-dimensional map Da_3M based on the existing 2-dimensional map D_2Ma (see FIG. 5A) and the 3-dimensional modeling information D_22.

A process of generating the 3-dimensional map Da_3M may include the process of generating the 3-dimensional map D_3M, which is described with reference to FIGS. 5A to 5C. In some embodiments, when the obstacle sensing module 432 senses the obstacle 23, the map generating module 500 may add the obstacle information D_23 to the 3-dimensional map Da_3M.

That is, the map generating module 500 may generate the 3-dimensional map Da_3M including the obstacle information D_23. In other words, the map generating module 500 may generate the 3-dimensional map Da_3M including an obstacle 23-present region and may indicate the obstacle 23-present region and other regions in different colors from each other to distinguish the obstacle 23-present region from the other regions. In some embodiments, when the map generating module 500 generates the 3-dimensional map Da_3M to which the obstacle information D_23 is added, the map generating module 500 may transmit the 3-dimensional map Da_3M to the plurality of vehicles 400.

That is, whenever the map generating module 500 generates the 3-dimensional map Da_3M, the map generating module 500 may collectively transmit the 3-dimensional map Da_3M to the plurality of vehicles 400. In other words, the plurality of vehicles 400 may collectively recognize the obstacle 23, which is sensed by one vehicle 400, via the map generating module 500. FIG. 9C illustrates that the control module 600 receiving the 3-dimensional map Da_3M transmits the control signal D_C to the plurality of vehicles 400.

In some embodiments, the control signal D_C may be a signal for adjusting the traveling path and speed of each of the plurality of vehicles 400.

The control module 600 may control driving of the plurality of vehicles 400, based on the 3-dimensional map Da_3M including the 3-dimensional modeling information D_22 measured in real time. That is, the driving of the plurality of vehicles 400 may be controlled by the control module 600, according to what has changed in the manufacturing line 22. In some embodiments, when the map generating module 500 transmits the 3-dimensional map Da_3M including the obstacle information D_23 to the control module 600, the control module 600 may transmit the control signal D_C to the plurality of vehicles 400.

That is, when at least one vehicle 400 senses the obstacle 23, the map generating module 500 may generate the 3-dimensional map Da_3M reflecting the obstacle information D_23, and the control module 600 may generate the control signal D_C for the plurality of vehicles 400 to avoid the obstacle 23. In other words, the control module 600 may collectively adjust traveling paths and speeds of the plurality of vehicles 400, based on the 3-dimensional map Da_3M including the obstacle information D_23. Even when at least one of the plurality of vehicles 400 senses the obstacle 23, the plurality of vehicles 400 may respectively change driving conditions thereof according to the position of the obstacle 23, via the control module 600. It should be understood that embodiments described herein should be considered in a descriptive sense only and not for purposes of limitation.

Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. An autonomous driving device comprising:
a plurality of vehicles configured to travel on a ceiling of a manufacturing line in which manufacturing equipment is arranged;
a traveling rail arranged along the ceiling of the manufacturing line to provide a movement path for each of the plurality of vehicles; a measurement module mounted on each of the plurality of vehicles and comprising a LiDAR sensor and a 3-dimensional sensor; and
a map generating module configured to receive information from the measurement module,
wherein the map generating module is further configured to generate a 3-dimensional map that 3-dimensionally represents the manufacturing line.

2. The autonomous driving device of claim 1, wherein the measurement module is configured to measure a structure of the manufacturing line and a position of the manufacturing equipment, when each of the plurality of vehicles is traveling.

3. The autonomous driving device of claim 2, wherein
a 2-dimensional map is a map representing the manufacturing line as a 2-dimensional grid structure, the measurement module is further configured to generate 3-dimensional modeling information and transmit the 3-dimensional modeling information to the map generating module, and
the 3-dimensional modeling information comprises information about the structure of the manufacturing line and a shape and the position of the manufacturing equipment.

4. The autonomous driving device of claim 3, wherein the map generating module is further configured to generate the 3-dimensional map, based on the 2-dimensional map and the 3-dimensional modeling information.

5. The autonomous driving device of claim 4, wherein the map generating module is further configured to transmit the 3-dimensional map to the plurality of vehicles.

6. The autonomous driving device of claim 4, wherein the map generating module is further configured to train the 2-dimensional map, based on the 3-dimensional map.

7. The autonomous driving device of claim 4, wherein the map generating module is further configured to generate the 3-dimensional map comprising a map in which the 3-dimensional modeling information missing from the 2-dimensional map is restored, by comparing the 3-dimensional modeling information with the 2-dimensional map.

8. The autonomous driving device of claim 4, wherein the 3-dimensional map divides the manufacturing line into a plurality of regions.

9. The autonomous driving device of claim 8, wherein
the plurality of regions comprise a first region and a second region, the first region is a region in which the manufacturing equipment abnormally operating is located, and
the second region is a region in which there is a difference between the 2-dimensional map and the 3-dimensional modeling information.

10. The autonomous driving device of claim 9, further comprising:
a display displaying the 3-dimensional map, wherein, on the display, the first region is shown in a first color, and the second region is shown in a second color that is different from the first color.

11. The autonomous driving device of claim 1, wherein the plurality of vehicles each have a space in which a conveying-object is loaded and are further configured to transport the conveying-object.

12. The autonomous driving device of claim 1, wherein the measurement module further comprises a vibration sensor and a noise sensor.

13. An autonomous driving device comprising:
a plurality of vehicles configured to travel on a floor of a manufacturing line in which manufacturing equipment is arranged; a measurement module mounted on each of the plurality of vehicles and configured to measure a shape and a position of the manufacturing equipment in real time;
a map generating module configured to transmit information to and receive information from the measurement module; and
a control module configured to control driving of the plurality of vehicles, wherein
the map generating module is further configured to generate a 3-dimensional map that 3-dimensionally represents the manufacturing line, and
the measurement module is further configured to generate 3-dimensional modeling information comprising information about a structure of the manufacturing line and the shape and position of the manufacturing equipment.

14. The autonomous driving device of claim 13, wherein the measurement module comprises an optical measurement device.

15. The autonomous driving device of claim 14, wherein the map generating module is further configured to store the position of the manufacturing equipment, which is measured by the measurement module, in the 3-dimensional map.

16. The autonomous driving device of claim 13, further comprising an obstacle sensing module configured to sense an obstacle.

17. The autonomous driving device of claim 16, wherein, when the obstacle sensing module senses the obstacle, the map generating module is further configured to add information of the obstacle to the 3-dimensional map.

18. The autonomous driving device of claim 17, wherein the map generating module is further configured to, when the map generating module adds the information of the obstacle to the 3-dimensional map, transmit the 3-dimensional map to the plurality of vehicles.

19. The autonomous driving device of claim 16, wherein the control module is further configured to, when the obstacle sensing module senses the obstacle, control driving of the plurality of vehicles.

20. An autonomous driving device comprising:
a plurality of vehicles configured to travel on a ceiling of a manufacturing line in which manufacturing equipment is arranged;
a traveling rail arranged along the ceiling of the manufacturing line to provide a movement path for each of the plurality of vehicles;
a measurement module mounted on each of the plurality of vehicles and comprising an optical measurement device;
a map generating module configured to receive information from the measurement module; and
a control module configured to control driving of the plurality of vehicles, wherein
the measurement module is configured to generate 3-dimensional modeling information,
the 3-dimensional modeling information comprises information of the traveling rail, information of the manufacturing equipment, and information of the manufacturing line,
the map generating module is further configured to generate a 3-dimensional map that 3-dimensionally represents the manufacturing line, based on a 2-dimensional map and the 3-dimensional modeling information, the 2-dimensional map representing the manufacturing line as a 2-dimensional grid structure, and
the map generating module is further configured to transmit the 3-dimensional map to the plurality of vehicles and the control module.
